(19) United States
(12) Patent Application Publication
(10) Pub. No.: US 2012/0211487 A1
(43) Pub. Date: Aug. 23, 2012

(54) MICROWAVE UNIT AND METHOD THEREFORE

(75) Inventors: Leif Bergstedt, Varberg (SE); Bengt Madeberg, Kungsbacka (SE)

(73) Assignee: Huawei Technologies Co., Ltd., Zhenzhen (CN)

(21) Appl. No.: 13/458,671

(22) Filed: Apr. 27, 2012

Related U.S. Application Data
(63) Continuation of application No. PCT/CN2010/080155, filed on Dec. 23, 2010.

(30) Foreign Application Priority Data
Dec. 31, 2009 (SE) PCT/SE2009/000545

(51) Int. Cl. H05B 6/64; H05K 3/30

(52) U.S. Cl. 219/679; 29/832

(57) ABSTRACT

A microwave unit comprising a motherboard and a package adapted to be assembled automatically in, e.g., a Surface Mounted Device, SMD, machine is disclosed. The microwave unit preferably comprises a connecting component interconnecting the motherboard and the package, and operable to make the signal ways on a same level at both the motherboard and at the package. Furthermore, the microwave unit preferably comprises a micro-strip adapted soldering tag for soldering on two sides.

### CROSS-REFERENCE TO RELATED APPLICATIONS

This application is a continuation of International Application No. PCT/CN2010/080155, filed on Dec. 23, 2010, which claims priority to International Patent Application No. PCT/SE2009/000545, filed on Dec. 31, 2009, both of which are hereby incorporated herein by reference in its entireties.

### FIELD OF THE APPLICATION

The present application relates to a microwave unit comprising a motherboard and a package adapted to be assembled automatically in a Surface Mounted Device, SMD, machine.

### BACKGROUND OF THE APPLICATION

There is a goal in the commercial microwave industry to fully automatize mass volume manufacturing of microwave units. To solve this problem, MMICs have been packaged in packages that are possible to attach and solder in a fully automatic Surface Mounted Device machine. A main problem with these packages is that it is difficult to have a controlled matched signal and ground way in to the package and out of the package.

The article “A 1-Watt Ku-band Power Amplifier MMIC using Cost-effective Organic SMD Package”, 34th European Microwave Conference—Amsterdam, 2004, by A. Bessemoulin, M. Parisot, P. Quentin, C. Saboureau, M. van Heijningen, J. Priday, relates to a microwave organic SMD power package. The MMIC is attached onto a thickened copper slug, within a cavity made in low-cost 8-mils R04003 substrate. The electrical interconnections are realized with gold bond wires connecting the MMIC pads to feed lines on the package front side, themselves connected to the package leads, through the package substrate by means of RF vias. After covering with a lid, the device can be mounted, by a reflow soldering technique for instance. The general principle with this solution is to “keep it small”.

U.S. Pat. No. 6,011,692 relates to an element for supporting one or more chips to facilitate the mounting thereof on circuit boards. The chip supporting element comprises a ductile foil of electrically and thermally conducting material, and a stabilizing frame of dielectric material fixed to the foil around the site where at least one chip is to be located in contact with the foil. For low-power applications, the chip supporting element would constitute a complete chip module to be mounted on a circuit board.

### SUMMARY OF THE APPLICATION

Problems in prior art are solved by a microwave unit according to claim 1. The microwave unit preferably comprises a motherboard and a package adapted to be assembled automatically in a Surface Mounted Device, SMD, machine. The microwave unit preferably also comprises a connecting component connected between the motherboard and the package, and operable to make the signal ways on the same level at both the motherboard and at the package. Furthermore, the microwave unit preferably comprises a micro-strip adapted soldering tag which is soldered at both sides.

An advantage with the microwave unit according to preferred embodiments of the present application is that the signal level will have an unbroken continuity in to and out from the package. A further advantage according to an aspect of the application is that it is possible to assemble microwave units automatically.

A further example advantage in this context is achieved if the microwave unit also comprises ground pads operable to align the package to the motherboard, and to make the ground level on the same level at both the motherboard and at the package. Hereby, a good mechanical structure is secured. Furthermore, it is also easier to implement copper sheets in the package.

According to one embodiment of the microwave unit, the connecting component comprises a wing means arranged over an air gap between the motherboard and the package, and operable to adjust the air gap in the connection area. Furthermore, the connecting component, according to the embodiment, preferably comprises a solder mask covering the wing means, and is operable to adjust the mean value of the dielectric constant at the air gap area. Hereby is achieved a good function of the signal connection between the component and the motherboard.

Furthermore, it is an advantage in this context if the connecting component also comprises soldering pads operable to connect the connecting component to the motherboard and to the package, and in that the solder mask also is operable to control the soldering points.

A further advantage in this context is achieved if the connecting component is a printed circuit board, PCB, made of laminate.

According to another embodiment of the microwave unit, the connecting component comprises ribbon-bonding operable to connect the motherboard and the package, and a wing means arranged over an air gap between the motherboard and the package, and operable to adjust the air gap in the connection area.

According to one embodiment of the microwave unit, the air gap has an inclining cross section. Hereby, a low influence to the signal properties is achieved even at higher frequencies.

According to another embodiment of the microwave unit, the air gap has a stepped cross section. Hereby, a low influence to the signal properties is achieved even at higher frequencies.

Furthermore, it is an advantage in this context if most of the heat sink is at the package.

A further advantage in this context is achieved if the heat sink is made of copper.

Furthermore, it is an advantage in this context if the motherboard comprises a ground layer, a dielectric layer upon the ground layer, and an upper layer upon the dielectric layer, wherein the ground, layer is thicker than the upper layer. Hereby, the heat distribution at the motherboard will be improved and it will also gain the MTBF.

A further advantage in this context is achieved if the package comprises a layer of silver epoxy that attaches a Monolithic Microwave Integrated Circuit, MMIC.

Furthermore, it is an advantage in this context if the microwave unit also comprises ribbon-bonding operable to connect the package and the MMIC.

It will be noted that the term “comprises/comprising” as used in this description is intended to denote the presence of a given characteristic, step or component, without excluding the presence of one or more other characteristic, features, integers, steps, components or groups thereof.

Embodiments will now be described with a reference to the accompanying drawings, in which:

### BRIEF DESCRIPTION OF THE DRAWINGS

FIG. 1 is a cross-sectional view of a microwave unit according to the present invention;

FIG. 2 is a side view of a first embodiment of a connecting component comprised in the microwave unit

FIGS. 3A and 3B are a side view and a top view, respectively, of a second embodiment of a connecting component comprised in the microwave unit;

FIG. 4 is a cross-sectional view of a first embodiment of an air gap included in the microwave unit;

FIG. 5 is a cross-sectional view of a second embodiment of an air gap included in the microwave unit;

FIGS. 6A and 6B are a top view and a side view, respectively, illustrating a micro-strip adapted soldering tag comprised in the microwave unit; and

FIG. 7 is a cross-sectional view illustrating the lower level of soldering surfaces comprised in the microwave unit.

### DETAILED DESCRIPTION OF THE EMBODIMENTS

A major disadvantage with the SMD package solution of 2004, referred to in the background section, is to provide heat transport from the package. A very good cooling must be attached directly under the centre of the package. A further disadvantage is that this package has frequency limitations because of the “zig-zag” way of the signal from the under side of the package. The problem is that as the ground and signal plane is not at the same level as the micro-strip structure at the motherboard there are limitations concerning upper frequency and signal losses. Typically there is a practically upper limit of some 40 GHz. Regarding the heat sink problem for Power Amplifier packages, this result in special printed circuit boards with in-laminated copper sheets; so called “coins” to spread out the heat from the package.

U.S. Pat. No. 6,011,692 as briefly described in the background section, e.g., does not disclose or suggest how to solve automatic manufacturing and how to handle mismatch of micro-strip conductor width between the module/package and the motherboard.

For high-power applications, the chip supporting element would have to be fixed to a heat sink on a circuit board, such as a mother board.

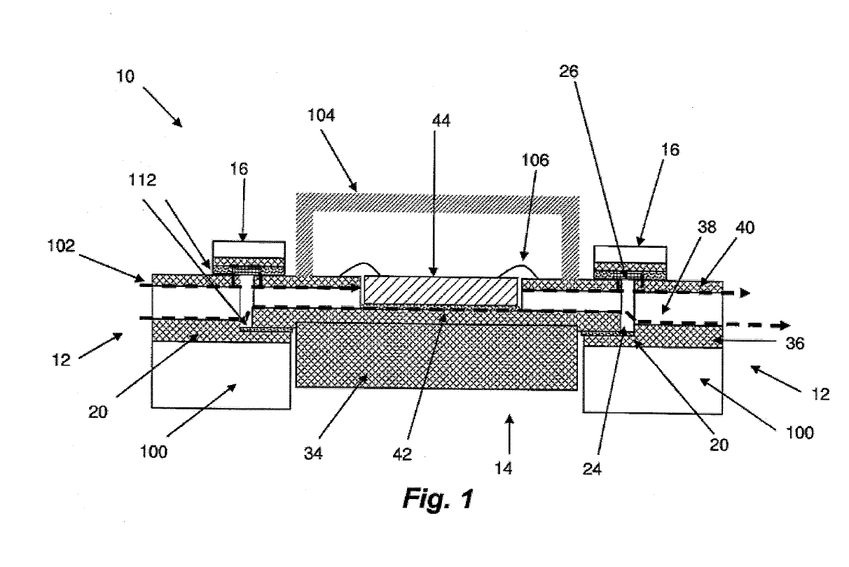

In FIG. 1 there is disclosed a cross-sectional view of a microwave unit 10. The microwave unit 10 comprises a motherboard 12 and a package 14. The microwave unit 10 is adapted to be assembled automatically in a Surface Mounted Device, SMD, machine. As also is apparent in FIG. 1, the microwave unit 10 comprises, in this case two, connecting components 16, each connected between the motherboard 12 and the package 14. The connecting component 16 is operable to make the signal ways 102 on the same level at both the motherboard 12 and at the package 14. Furthermore, the microwave unit 10 also comprises ground pads 20, operable to align the package 14 to the motherboard 12. The ground pads 20 are also operable to make the ground level on the same level at both the motherboard 12 and at the package 14. As also is apparent in FIG. 1, there is an air gap 24 between the motherboard 12 and the package 14, and the connecting component 16 is arranged over the air gap 24.

The motherboard 12 comprises a number of layers, namely a multi-layer PCB 100 of glass epoxy that also is the mechanical carrier, a ground layer 36, a dielectric layer 38, and an upper layer 40. The upper layer 40 comprises copper foil coated with e. g. Ni/Au, or Ni/Pd/Au, or Ag/Au. The ground layer 36 is thicker than the upper layer 40.

As also is apparent in FIG. 1, the package 14 comprises a layer 42 of silver epoxy that attach a Monolithic Microwave Integrated Circuit, MMIC, 44. Beneath the layer 42 is a heat sink means 34, made of e. g. copper or brass, coated with e. g. Ni/Au.

Also indicated in FIG. 1 are solder 112, a cap 104 arranged over the MMIC 44, and bond wires 106 connecting the MMIC 44 to the package 14.

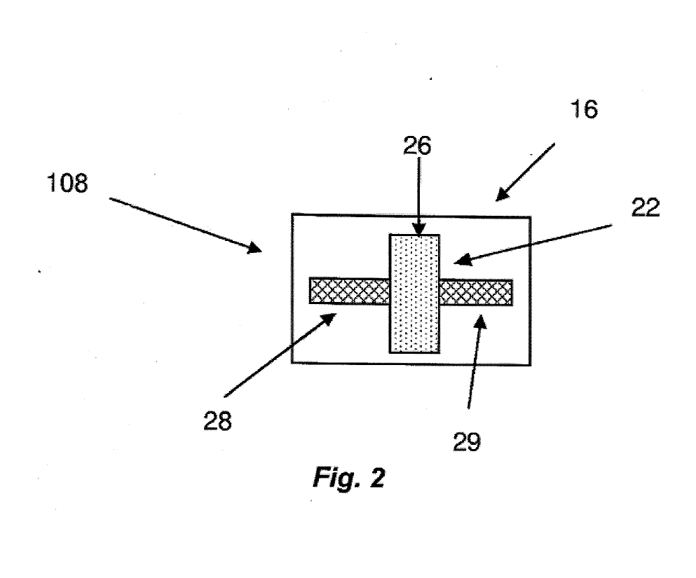

In FIG. 2 there is disclosed a side view of a first embodiment of the connecting component 16. The side that is disclosed in FIG. 2 is the side of the connecting component 16 facing on to the motherboard 12, the air gap 24, and the package 14. The connecting component 16 comprises a wing means 22 arranged over the air gap 24 between the motherboard 12 and the package 14. The wing means 22 is operable to adjust the air gap 24 in the connection area. Furthermore, the connecting component 16 comprises a solder mask 26, covering the wing means 22 and operable to adjust the mean value of the dielectric constant at the air gap area. As also is apparent in FIG. 2, the connecting component 16 also comprises soldering pads 28, 29 operable to connect the connecting component 16 to the motherboard 12 and to the package 14. Furthermore, the solder mask 26 is also operable to control the soldering points. Also disclosed in FIG. 2 is the laminate 108. This connecting component 16 is a vital part to get good function of the signal connection between the MMIC 44 and the motherboard 12.

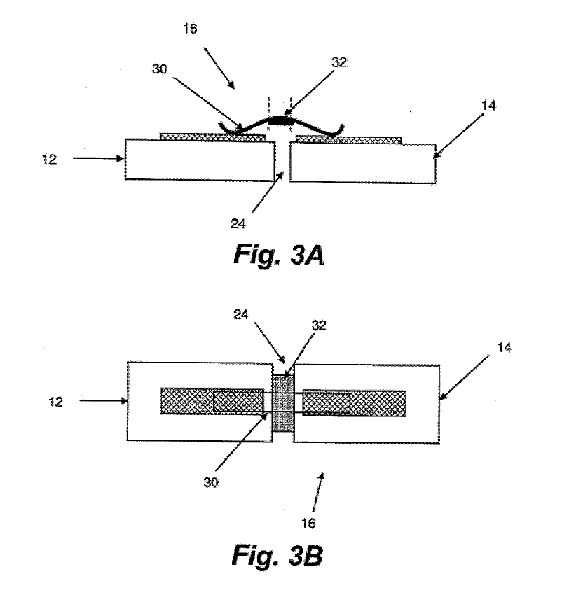

In FIGS. 3A and 3B there are disclosed a side view and a top view, respectively, of a second embodiment of the connecting component 16. In this particular embodiment, the connecting component 16 comprises ribbon-bonding 30 operable to connect the motherboard 12 and the package 14. Furthermore, the connecting component 16 also comprises a wing means 22 arranged over the air gap 24 between the motherboard 12 and the package 14. As in the first embodiment, the wing means 22 is operable to adjust the air gap 24 in the connection area. In FIG. 3A there is schematically disclosed, between the broken lines, the so called wing part of the ribbon-bonding 30.

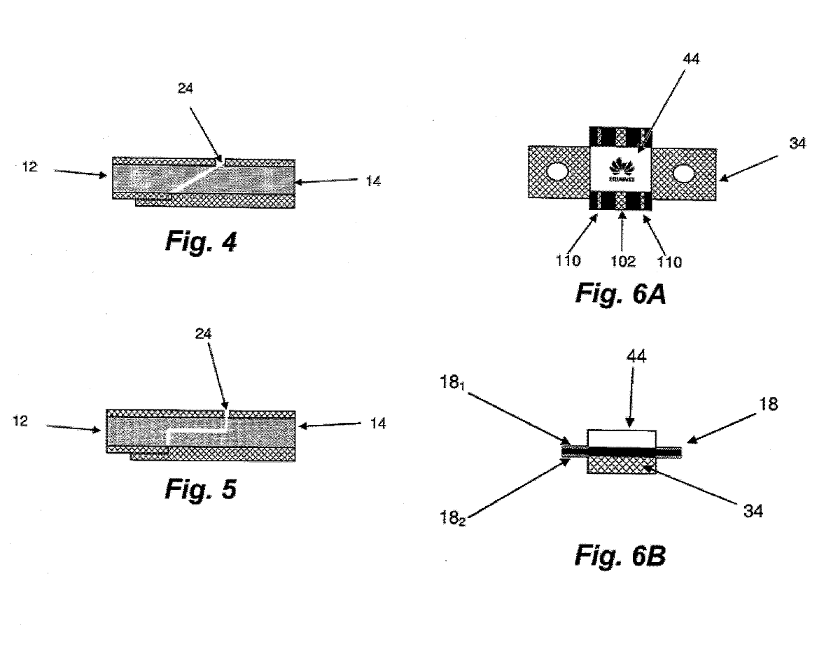

The air gap 24 between the motherboard 12 and the package 14 should normally be very short and have a low influence on the signal properties. However, with higher frequencies this could be more critical. The reason for the problems is that the conductor dimensions at the air gap 24 will be more adapted to the conditions at the motherboard 12 and the package 14 as the dielectric is set by the laminates. Here the dielectric constants are some 2.3 to 3.5. In the air gap 24 there is only air with a dielectric constant Dk of 1. A way to handle this is to design the air gap 24 in a special way, as in FIGS. 4, and 5.

In FIG. 4 there is disclosed a cross-sectional view of a first embodiment of the air gap 24. In this embodiment, the air gap 24 has an inclining cross section. It is pointed out that it is the same or corresponding cross-section that is disclosed in both FIG. 1 and FIG. 4, while illustrated as a step in FIG. 1.

In FIG. 5 there is disclosed a cross-sectional view of a second embodiment of the air gap 24. In this particular embodiment the air gap 24 has a stepped cross section. It is pointed out that it is the same or corresponding cross-section that is disclosed in both FIG. 1 and FIG. 5.

With the air gap 24 designed either as disclosed in FIG. 4 or in FIG. 5, and if we assume the worst case of 50% air and 50% laminate, wherein the laminate has a dielectric constant Dk of 3.5, the result will be Dk=/2=2.25. This implies a less difference between the dielectric constants than in the case disclosed in FIG. 1.

In FIGS. 6A and 6B there are disclosed a top view and a side view, respectively, illustrating a micro-strip adapted soldering tag 18 comprised in the microwave unit 10. As is apparent in FIG. 6B, the soldering tag 18 is soldered at both sides 181 and 182. Also disclosed is the MMIC 44, and the heat sink means 34, here in the form of copper flanges. Also disclosed in FIG. 6A are the signal way 102, and the bias ways 110.

The version disclosed in FIGS. 6A and 6B is a proposed version for microwave radios. However, depending of radio-application the versions can be of several types. For radio links it is often good to move the heat in direction “up” because there is always an Al-shielding of the microwave unit. Furthermore, the diplexer is also often attached to this shielding.

A version, not disclosed in a figure, for Base-radio PA will probably have a bigger metal carrier and be designed to have the heat transport downwards.

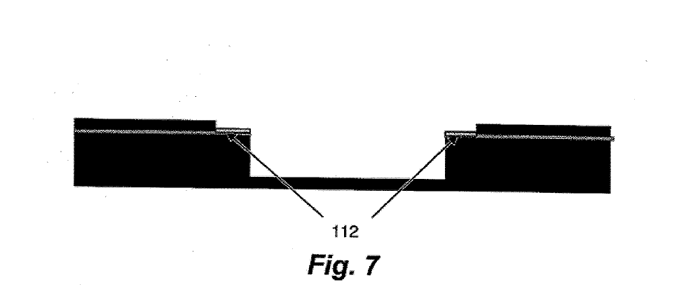

In FIG. 7 there is disclosed a cross-sectional view illustrating the lower level of soldering surfaces comprised in the microwave unit 10. In FIG. 7 there is disclosed the soldering paste 112, which must be disposed by automatic pipe or manual, when assembling at an SMD-line.

The motherboard 12 is normally implemented by normal PCB manufacturing, except the clearance of the ground under the microwave laminate. However, this can be produced in two different ways:
By laser-cut if the laminate permit this.
By contact milling. However, then we need a 70 μm copper foil under the microwave laminate. Normally the ground layer 36 under the microwave dielectric 38 is just 18 μm because microwave laminate mostly are sold with 18 μm copper at both sides. IN our case we will need 18 μm at one side and 70 μm at the other side. But the thicker 70 μm Cu will improve the heat distribution at the microwave board and gain the MTBF.

The idea with the package 14 is to base the design with the new version of TAC-LAM-plus. However, other laminates are possible. A typical built up of the laminate can be 18 μm Cu+100 μm PTFE+1-2 mm Cu. The general idea is to have the laminate “chip-thick” so when the pocket for the chips is laser milled and the chip attached, the chip surface shall be at the same level as the dielectric at the package 14. The carrier—mostly copper—is pre-milled before manufacturing. The process of producing the package 14 will probably include one lamination step, a couple of laser drilling/milling steps, and probably two copper plating steps.

The total effects of the embodiments can be summarized as follows:
Possible to have automatic assembled packages 14 up to at least 80 GHz.
Better performances than for existing packages even at some 2 GHz.
Simpler microwave boards than today because most of the heat sink infrastructure will be at the package 14.
Possible to assemble MMICs in packages 14 for one chip/MMIC. This implies that it is possible to assemble the microwave units 10 with the aid of a Pick-and-Place machine. If a chip is being breaked, when using a package 14 for one chip, then it is possible to solder away the broken component, and to solder a new one in place. It is also possible to test the chip in the package 14.

The claims are not limited to the described embodiments. It will be evident for those skilled in the art that many different modifications are feasible within the scope of the following Claims.

1. A method of interconnecting a microwave package and a motherboard in a Surface Mounted Device, SMD, comprising:
providing a motherboard;
arranging on the motherboard electrical circuitry other than a microwave package; and
aligning a signal path of the motherboard and a layer of the microwave package in a single plane.

2. The method according to claim 1, further comprising connecting the signal path of said motherboard and the layer of the microwave package via a component that comprises a planar electrically conducting surface and a solder mask.

3. The method according to claim 2, wherein the signal path of the motherboard and the layer of the microwave package are aligned with a signal path or layer of an MMIC or a microwave power amplifier included in the microwave package.

4. The method according to claim 1, wherein a profile of a hole in the motherboard is shape adapted to a profile of the microwave package.

5. The method according to claim 4, wherein the hole in the motherboard is cut by milling.

6. The method according to claim 4, wherein the microwave package includes a heat sink and wherein the heat sink is attached to a ground layer of the microwave package.

7. The method according to claim 6, wherein the heat sink and the hole of the motherboard provide a heat transport through the heat sink and the hole of the motherboard, and wherein the heat transport is greater than transport in the motherboard of heat from the microwave package during operations.

8. A microwave unit comprising:
a motherboard;
a microwave package configured to be assembled automatically in an SMD machine;
a connecting component configured to interconnect the motherboard and the microwave package, and to provide signal paths on a same level at both the motherboard and at the microwave package; and
a microstrip soldering tag soldered at both sides of the component.

9. A microwave unit according to claim 8, further comprising ground pads configured to align the microwave package to the motherboard, and to provide a ground level on the same level at both the motherboard and at the microwave package.

10. A microwave unit according to claim 8, wherein the connecting component comprises:
a wing member arranged over an air gap between said motherboard and said package, that is configured to adjust the air gap in a connection area; and
a solder mask covering the wing member that is configured to adjust a mean value of a dielectric constant at the air gap area.

11. A microwave unit according to claim 10, wherein the connecting component further comprises soldering pads configured to connect the connecting component to the motherboard and to the microwave package, wherein the solder mask is further configured to control positioning of soldering points.

12. A microwave unit according to claim 11, wherein the connecting component is a printed circuit board that comprises a laminate.

13. A microwave unit according to claim 8, wherein the connecting component comprises ribbonbonding configured to connect the motherboard and the microwave package, and a wing member arranged over an air gap between the motherboard and the microwave package that is configured to adjust the air gap in a connection area.

14. A microwave unit according to claim 10, wherein the air gap has an inclining cross section.

15. A microwave unit according to claims 10, wherein the air gap has a stepped cross section.

16. A microwave unit according to claim 8, wherein the microwave package further comprises a heat sink.

17. A microwave unit according to claim 16, wherein the heat sink is made of copper.

18. A microwave unit according to claim 8, where the motherboard comprises a ground layer, a dielectric layer disposed over the ground layer, and an upper layer disposed over the dielectric layer, wherein the ground layer is thicker than the upper layer.

19. A microwave unit according to claim 8 wherein the microwave package comprises a layer of silver epoxy that attaches to a Monolithic Microwave Integrated Circuit (MMIC).

20. A microwave unit according to claim 8, wherein the microwave unit further comprises ribbonbonding configured to connect the microwave package and an Monolithic Microwave Integrated Circuit (MMIC).
